(19) United States
(12) Patent Application Publication
(10) Pub. No.: US 2007/0183234 A1
(43) Pub. Date: Aug. 9, 2007

(54) Semiconductor memory device having reduced voltage coupling between bit lines

(75) Inventors: Gong-Heum Han, Hwaseong-gun (KR); Chul-Sung Park, Seoul (KR); Hyung-Jin Kim, Bucheon-si (KR); Byeong-Uk Yoo, Yongin-si (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/527,088

(22) Filed: Sep. 26, 2006

(30) Foreign Application Priority Data
Jan. 27, 2006 (KR) 10-2006-0008789

(51) Int. Cl. G11C 7/00

(52) U.S. Cl. 365/203

(57) ABSTRACT

An enhanced semiconductor memory device capable of eliminating or minimizing a cell data flip phenomenon caused by capacitive voltage coupling between bit lines in different bit line pairs. Each memory cell is connected to a word line and between a pair of bit line. A first precharging and equalizing circuit us connected to a first bit line pair and a second precharging and equalizing circuit us connected to an adjacent second bit line pair. The first and second precharging and equalizing circuit are activated independently and at different times in order to reduce voltage coupling between neighboring bit lines in different bit line pairs, thereby minimizing or eliminating a cell data flip phenomenon of a neighboring memory cell caused by voltage coupling between bit lines.

### CROSS-REFERENCE TO RELATED APPLICATION

This application claims the benefit under 35 U.S.C. §119 of Korean Patent Application No. 10-2006-0008789, filed Jan. 27, 2006, the disclosure of which is hereby incorporated by reference in its entirety.

### BACKGROUND OF THE INVENTION

1. Technical Field

The present invention relates to a semiconductor memory device, and more particularly, to a volatile semiconductor memory device such as a static random access memory (SRAM) having reduced of bit line (capacitive) voltage coupling.

2. Discussion of Related Art

Contemporary high performance consumer electronics such as the portable multimedia player (PMP), the personal computer and electronic communication devices (e.g., cellular phones) include large volatile semiconductor memory devices such as an SRAM having high speed operation and high integration. Low power consumption and reliability during high speed operation are especially important in a semiconductor memory devices employed in a battery operated systems such as cell phones and notebook computers. Accordingly, semiconductor manufacturers are constantly trying to reduce operating current and standby current in high integration memory cells in order to provide a mobile oriented low-power solution, and to solve a problem with stability associated with stored data in order to provide highly reliable operation.

In a conventional high integration semiconductor memory device, it is difficult to obtain cell stability due to (capacitive) bit line voltage coupling with neighboring memory cells. Thus it is difficult to obtain a dynamic noise margin and in a write operation for storing data in a selected memory cell or in a read operation for obtaining data from a selected memory cell. Accordingly, reliability of the write and read operations may be degraded.

FIG. 1 is a circuit diagram of a representative portion of a cell core circuit of a conventional SRAM. Referring to FIG. 1, a memory cell array 10 includes a plurality of SRAM cells 1 each having six CMOS transistors P1, P2, and N1 N2, N3 and N4. A precharging and equalizing unit 20, a column path 30, an equalizing driver 40, a write driver (WDR) 50, and a sense amplifier (SenseAmp) 60 constitute the SRAM cell core circuit having a connection structure as shown in FIG. 1 in order to effectively store write data in a selected memory cell within the memory cell array 10 and read the data from the selected memory cell.

The precharging and equalizing unit 20 includes a plurality of precharging and equalizing circuits (comprised of transistors P5, P6, and P7) each of which precharge and equalize a bit line pair including a bit line and a bit line bar to a set voltage level. In a read operation, the sense amplifier 60 senses and amplifies a voltage difference developed on a read section data line pair RSDL/RSDLB in response to a sensing enable signal PSA. In a write operation, the write driver 50 drives write data DIN to a write section data line pair WSDL/WSDLB in response to a write driving signal PWD. The column path 30 switches (connects) the bit line pair to the section data line pair in response to a column select enable signal Y/Yb.

If the pitch of an SRAM cell is substantially scaled down to the current resolution limit of a photolithography process according to a high integration demand, the six transistors constituting the memory cell in FIG. 1 may be divided and three-dimensionally laid out on different layers, not necessarily on the same layer. One memory cell 1 in the memory cell array 10 stores 1 bit (0 or 1) of data, in which the local transistors P1 and P2 have a source connected to a power voltage VDD, and access (or path) transistors N3 and N4 have a drain (or source) connected to one bit line Bli or the other bit line BLBi of a bit line pair BLi and BLBi (where, i is 0, 1, 2, 3 . . . n).

In FIG. 1, a plurality of memory cells 1 are connected to the bit line pairs BLi and BLBi disposed in a bit line direction. A last (nth) memory cell on each column is adjacent to a corresponding unit precharging and equalizing circuit 2 within the precharging and equalizing unit 20. A column path gate 4 including four transistors P8, P9, N5 and N6 is connected to the corresponding unit precharging and equalizing circuit 2 having a connection to the bit line pair BLi and BLBi. The column path gate 4 switchably connects the bit line pair BLi and BLBi to the read and write section data lines RSDL, RSDLB, WSDL and WSDLB. In the column path gate 4, PMOS transistors P8 and P9 transfer memory cell data developed on the bit line pair BLi and BLBi to the read section data line pair RSDL and RSDLB in response to a complementary column select signal Yb (e.g., Yb_S). The NMOS transistors N5 and N6 function to transfer write data from the write section data line pair WSDL and WSDLB to the bit line pair BLi and BLBi in response to a column select signal Y (e.g., Y_S_. In FIGS. 1 and 3, the suffix “_S” is an initial representing “select” and “_DS” are initials representing “deselected” (i.e., unselected). For example, Y_S indicates a column select signal applied to a selected column, and Y_DS indicates a column select signal applied to an unselected column. The write data is provided to the write section data line pair WSDL and WSDLB by an output of the write driver 50.

An equalizing control signal YEQS for causing precharging and equalization when actively applied to the precharging and equalizing unit 20 of FIG. 1 is otherwise at a logic low state of a standby mode. The equalizing control signal YEQS is brought to a (active) high logic state in a data access mode of operation (or an active mode) in which read or write operation is performed. The equalizing signal YEQS is generated by the equalizing driver 40. The equalizing driver 40 receives a precharging and equalizing control signal PYEQ from an equalizing generator (not shown) in the memory device. When the equalizing signal YEQS falls to a logic low state, the precharging transistors P5 and P6 and the equalizing transistor P7 are turned ON, such that a voltage level on the bit line pair BLi and BLBi is precharged at the level of an operation voltage (normally, VDD).

A write operation for storing data in a memory cell in the circuit of FIG. 1 having the structure as described above is generally performed as follows: In the write operation, a word line enable signal SWL of a particular row, a write driving enable signal PWD, and the equalizing signal YEQS are provided at a high state. Accordingly, the precharging transistors P5 and P6 and the equalizing transistor P7, which are turned ON in the standby mode, are turned OFF and the bit line pair Bli and BLBi are changed to a floating state.

The write driver 50 provides write data on the data input DIN to the write section data line pair WSDL and WSDLB in response to the write driving enable signal PWD. For example, the NMOS transistors N5 and N6 connected to the first bit line pair BL0 and BLB0 are turned ON in response to activation of the column select signal Y_S in order to store write data in a memory cell 1 located at an intersection between a (selected) first row and a first column. Accordingly, the write data is transferred from the write section data line pair WSDL and WSDLB to the bit line pair BL0 and BLB0 at a full swing level and to data nodes of the access transistors N3 and N4 in the memory cell 1 connected to the selected word line SWL_0, such that the write data is stored in (written to) the selected memory cell 1.

However, because a parasitic capacitor CBLa exists between the bit lines (e.g., BLB0 and BL1) connected to the different neighboring memory cells (different columns) as shown in FIG. 1, voltage coupling occurs between bit lines, particularly in the write operation. Strong voltage coupling causes a voltage level on the bit line BL1 to be significantly affected by a voltage level on the adjacent bit line bar BLB0, such that data already stored in the neighboring memory cell connected to the enabled word line SWL_0 is flipped from 0 to 1 or from 1 to 0.

A data flip phenomenon due to voltage coupling between bit lines in a conventional write mode of operation will be described with reference to the accompanying drawings.

FIG. 2 is a circuit block diagram illustrating a memory cell array structure in which memory cells of FIG. 1 are connected to bit line pairs, FIG. 3 is a timing diagram illustrating the operation timing for various signals in FIG. 1, and FIG. 4 is a timing diagram illustrating simulation waveforms of various signals in FIG. 1.

It is assumed in FIG. 2 that write data “0” is to be written into memory cell Y1_0 while cell data “0” is stored in adjacent memory cell Y0_0 and in adjacent memory cell Y2_0. In a write mode of operation, the word line SWL_0 is enabled in a high state as shown in waveform SWL in FIG. 3, and a selected bit line BL1 is discharged to a low level as shown in a waveform BL in FIG. 3, and the selected bit line bar BLB1 is kept at a high state as shown in the waveform BLB_S in FIG. 3. In this case, when the select bit line BL1 is discharged to a low level, a voltage level on an adjacent unselected bit line bar BLB0 is reduced according to the discharge operation as shown in the waveform BLB_DS in FIG. 3 by a voltage coupling operation of parasitic capacitors C1 and C2. Accordingly, data on an adjacent data node NO2 is changed to 0 and data on its complementary data node NO1 is changed to 1, such that cell data in the neighboring memory cell Y0_0 storing cell data “0” is flipped into “1.” In FIG. 2, reference numeral CBL01 indicates bit line voltage coupling between the first bit line bar BLB0 and the adjacent second bit line BL1.

As a further illustration, it is assumed that write data “1” is to be written into memory cell Y1_0 while cell data “1” is stored in memory cell Y0_0 and in memory cell Y2_0. The word line SWL_0 is enabled into a high state as shown in the waveform SWL in FIG. 3, the selected bit line bar BLB1 is discharged to a low level as shown in the waveform BLB_S in FIG. 3, and the selected bit line BL1 is kept at a high state as shown in the waveform BL in FIG. 3. In this case, when the selected bit line bar BLB1 is discharged to a low level, a voltage level on the adjacent unselected bit line BL2 is reduced according to the discharge operation as shown in the waveform BLB_DS in FIG. 3 by voltage coupling operation of parasitic capacitors C3 and C4. Accordingly, cell data in a neighboring memory cell Y2_0 storing cell data “1” may be flipped to “0.” In FIG. 2, reference numeral CBL12 indicates bit line voltage coupling between the second bit line bar BLB1 and the adjacent third bit line BL2.

As a result, in the conventional write operation having the operation timing as shown in FIG. 3, bit line voltage coupling as is further illustrated in the bottom of FIG. 4 may change data stored in a neighboring cell. This causes the failure of the storage function and/or read operation. It is apparent that reliability of data storage is more vulnerable in a closely packed high integration memory cell.

In FIG. 4, each horizontal axis indicates time in microseconds and each vertical axis indicates voltage V. The simulation waveform will be easily understood by those skilled in the art because reference numerals on the simulation waveform are the same as or similar to the reference numerals shown in FIGS. 1 and 3. For example, Y<1> indicates the column select signal Y, YEQS indicates the equalizing signal YEQS, and SWL indicates a selected word line (or a section word line).

Meanwhile, even in the read operation of reading data from the memory cell using the sense amplifier in the circuit of FIG. 1, bit line voltage coupling may cause a read failure. This will be described with reference to FIG. 13.

FIG. 13 is a combination of circuit diagram and timing diagram illustrating voltage coupling between bit lines during a read operation in a conventional bit line layout structure. A plurality of bit lines BL<0>, BLb<0>, BL<1>, BLb<1>, BL<2> and BLb<2> and parasitic capacitances between the bit lines are schematically shown on the left side (circuit diagram) of FIG. 13. The arrow AR1 indicates the case where data is read from a memory cell connected to the bit line pair BL<1>and BLb<1> when data “1” (“D1”) is stored in three neighboring memory cells in the same row (on the same word line). Unfortunately, a read error is caused since capacitive voltage coupling occurs between the bit lines in the read operation, as indicated by reference numeral 13a. The arrow AR2 indicates a case where data is read from a memory cell connected to the bit line pair BL<1> and BLb<1> when data “0”, “1” and “0” are respectively stored in the three neighboring memory cells in the same row (on the same word line). In this case, read success is achieved because voltage coupling between the bit lines does not occur in the read operation, as indicated by reference numeral 13b.

In the read-failure case indicated by reference numeral 13a, when the word line is enabled, the adjacent unselected bit line bar BLb<0> is shifted to a low level (by stored data) and the selected bit line BL<1> is shifted to a high level (by stored data). However, voltage coupling due to a parasitic capacitor between the unselected bit line bar BLb<0> and the selected bit line BL<1> makes the level actually established on the selected bit line BL<1> much lower than a normal level that would result when there is no voltage coupling. Accordingly, a potential difference developed between the selected bit line BL<1> and the selected bit line bar BLb<1> may be smaller than the sensing margin, thereby causing read operation failure in the sense amplifier.

As a result, it can be seen that reliability of the read operation is degraded since bit line voltage coupling strongly or weakly occurs depending on the actual values of the cell data stored in the neighboring memory cells even though there is a constant parasitic capacitance.

As described above, bit line voltage coupling may cause cell data flip in the write operation and the read error in the read operation.

### SUMMARY OF THE INVENTION

An aspect of the present invention provides a semiconductor memory device capable of effectively maintaining stability of memory cells in a high integration static random access memory (SRAM).

Another aspect of the present invention provides a semiconductor memory device capable of minimizing or reducing voltage coupling between bit lines in a data access mode of operation.

Another aspect of the present invention provides an enhanced semiconductor memory device capable of eliminating or minimizing a cell data flip phenomenon caused by voltage coupling between bit lines.

Another aspect of the present invention provides a static random access memory capable of eliminating or minimizing a cell data flip phenomenon in a write mode of operation in a static random access memory having full CMOS memory cells.

Another aspect of the present invention provides a static random access memory capable of effectively eliminating line coupling noise due to a bit line voltage swing in write and read operation.

Exemplary embodiments of the present invention provide a semiconductor memory device that includes: a memory cell array (having a plurality of memory cells) each memory cell connected to a word line and between a pair of bit lines (a bit line pair); a first precharging and equalizing circuit connected to a first bit line pair connected to a first memory cell connected to the first word line; and a second precharging and equalizing circuit connected to a second bit line pair connected to a second memory cell connected to the first word line, wherein the first memory cell is adjacent to the second memory cell; and a third precharging and equalizing circuit connected to a third bit line pair connected to a third memory cell connected to the first word line, wherein the third memory cell is adjacent to the second memory cell.

A bit line coupling reduction unit (e.g., an equalizing driver) configured to first apply an equalization release signal to the first precharging and equalizing circuit when a data access mode of operation is initiated, and to then apply equalization release signals to the second and third precharging and equalizing circuits after a predetermined time lapses. This independent operation of the precharging and equalizing circuits reduces voltage coupling between neighboring bit lines in different bit line pairs.

The bit line pairs may be twisted per each predetermined number of word lines. For example, the twisted-pair bit line pairs may be twisted every 1024 word lines.

Further, the equalizing driver may operate sixteen precharging and equalizing circuits (including the first, second and third precharging and equalizing circuits). A word line connected to a selected memory cell having a connection to the selected bit line pair may be enabled a predetermined time after a precharging and equalizing circuit connected to the selected bit line pair is disabled.

A word line connected to a selected memory cell having a connection to the selected bit line pair may be enabled when the precharging and equalizing circuit connected to the (adjacent) unselected bit line pair is disabled.

The semiconductor memory device may be a static random access memory (SRAM) including a plurality of memory cells, each memory cell including six transistors. The six transistors may comprise three-dimensional stack memory cells formed on different conductive layers.

Other embodiments of the present invention provide semiconductor memory devices that include: a memory cell array (having a plurality of memory cells connected in a matrix of rows and columns), each memory cell being connected to a word line and between a pair of bit lines; and an equalizing driver for applying an equalization release signal to first precharging and equalizing circuit connected to a first bit line pair, and then applying equalization release signals when a word line is activated after a write driver is enabled, to other (second, third etc.) precharging and equalizing circuits connected to a plurality of other (e.g., unselected) bit line pairs, thereby reducing voltage coupling between adjacent bit lines of different bit line pairs during a write mode of operation.

With the configuration and operation of the device according to embodiments of the present invention, bit line voltage coupling between bit lines of neighboring memory cells is minimized or reduced and thus reliability of write and read operations is assured.

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. Other examples, known methods, procedures, conventional dynamic random access memories and circuits will be not described so that the present invention is not ambiguous.

### BRIEF DESCRIPTION OF THE DRAWINGS

The above and other features of the present invention will become more apparent to those of ordinary skill in the art by describing in detail preferred embodiments thereof with reference to the attached drawings in which:

FIG. 1 is a circuit diagram of a representative portion of a cell core circuit of a conventional SRAM;

FIG. 2 is a circuit block diagram illustrating the memory cell array structure in which memory cells of FIG. 1 are connected to capacitively coupled bit line pairs;

FIG. 3 is a timing diagram illustrating the operation timing for various signals in FIG. 1;

FIG. 4 is a timing diagram illustrating simulation waveforms of various signals in FIG. 1;

FIG. 5 is a circuit diagram of a representative portion of a cell core circuit of an SRAM according to an embodiment of the present invention;

FIG. 6 is a circuit diagram illustrating an equalizing driver in FIG. 5;

FIG. 7A is a timing diagram illustrating operation timing for various signals in the SRAM of FIG. 5;

FIG. 7B is a timing diagram illustrating simulation waveforms of various signals in the SRAM of FIG. 5;

FIGS. 8A and 8B are timing diagrams illustrating a comparison in write operation timing between a conventional technique and an embodiment of the present invention, respectively;

FIG. 9 is a timing diagram illustrating simulation waveforms of write operation in the SRAM of FIG. 5;

FIG. 10 is a timing diagram illustrating operation timing for various signals in the equalizing driver shown in FIG. 6;

FIG. 11 is a circuit diagram illustrating an implementation of a write driver in the SRAM of FIG. 5;

FIG. 12 is a circuit diagram illustrating an implementation of a sense amplifier in the SRAM of FIG. 5;

FIG. 13 is a combination of circuit diagram and timing diagram illustrating capacitive voltage coupling between bit lines during a read operations in a conventional bit line layout structure; and

FIG. 14 is a wiring diagram illustrating a bit line layout structure, solving a capacitive coupling problem in FIG. 13, according to a variant of the present invention.

### DETAILED DESCRIPTION OF PREFERRED EMBODIMENTS

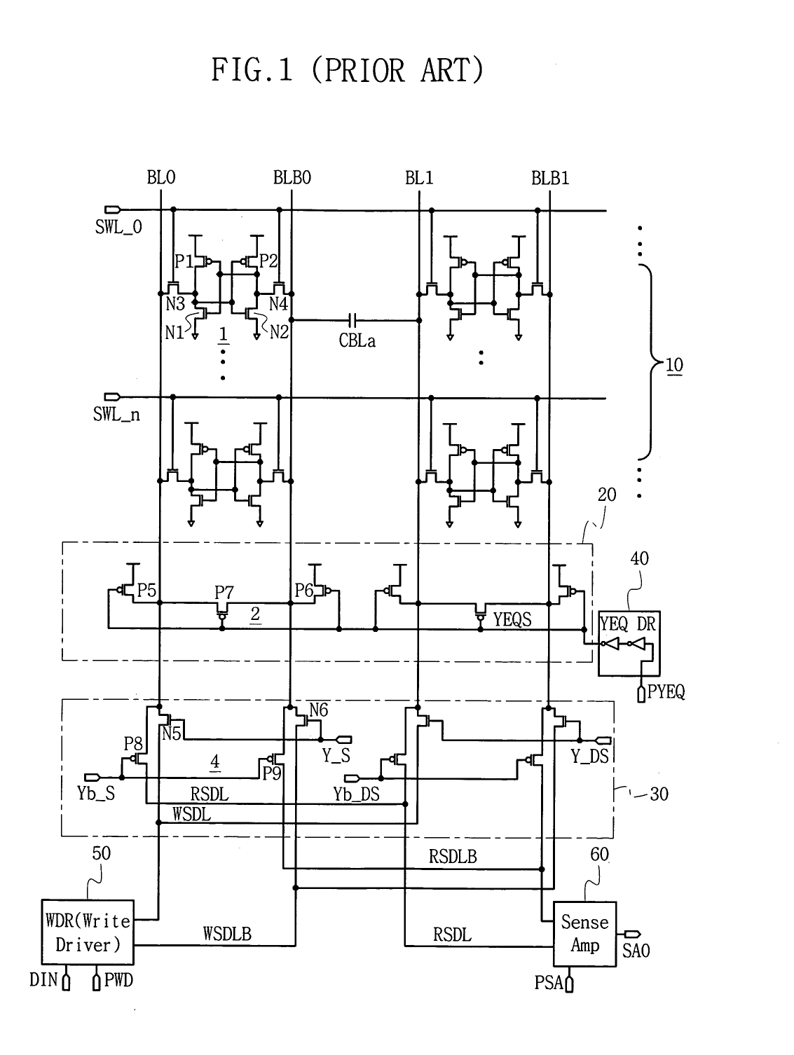

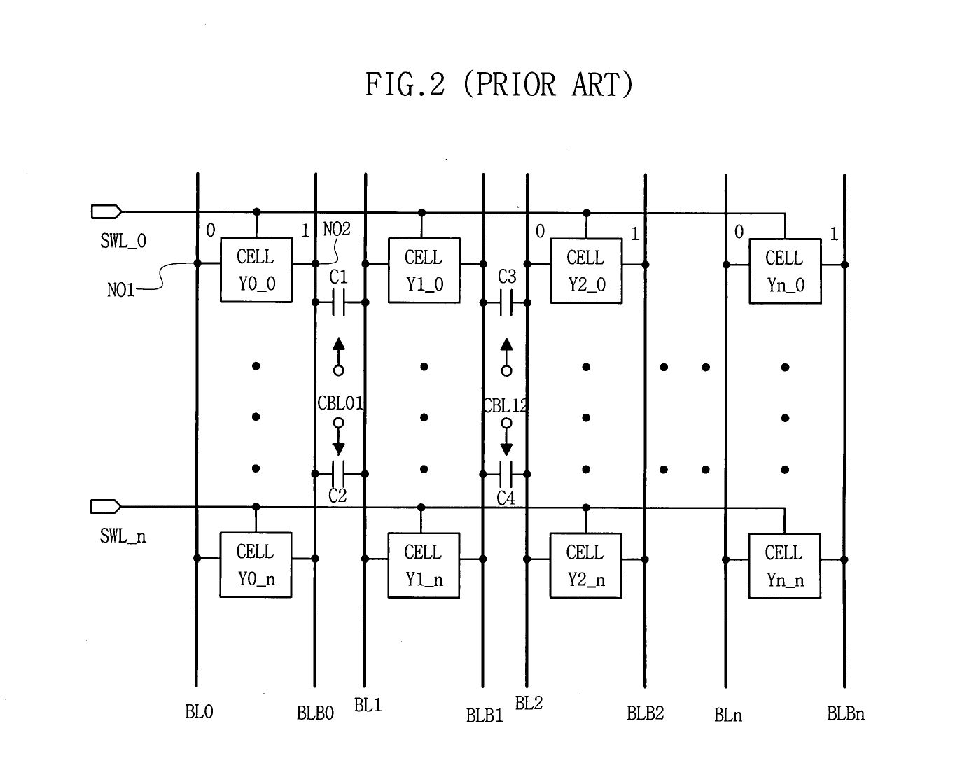

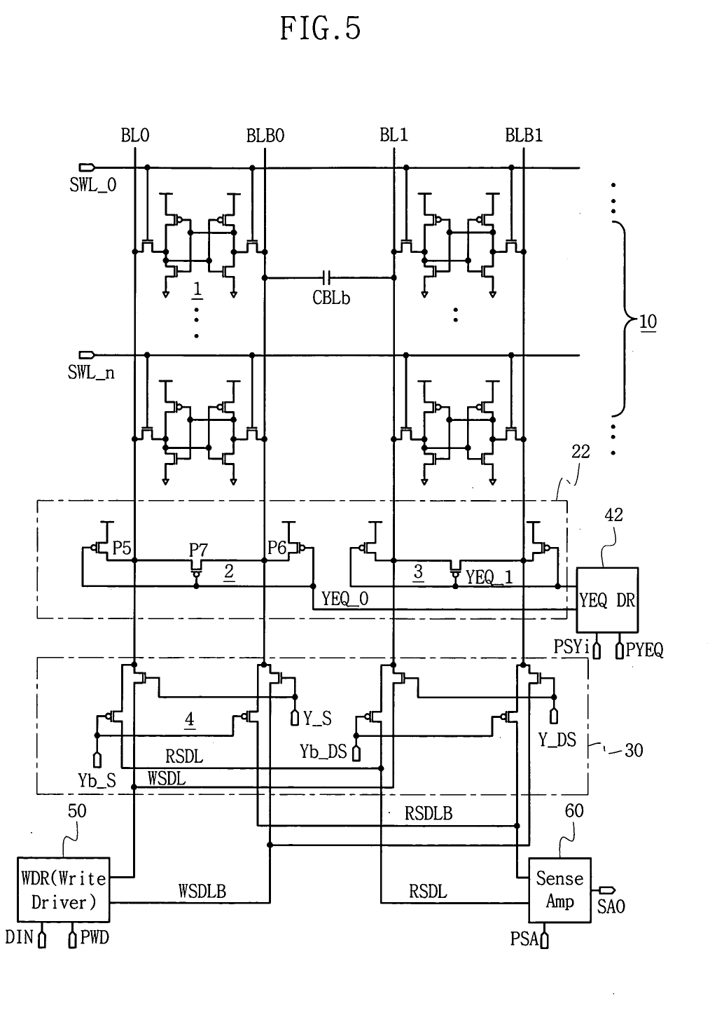

FIG. 5 is a circuit diagram of a representative portion of a cell core circuit of an SRAM according to an embodiment of the present invention. The conventional technique described with reference to FIGS. 1 to 4 and 13 provides a basis for understanding the operation present invention. The cell data flip phenomenon during a write operation and a sensing error in a read operation due to capacitive voltage coupling between bit lines was described in detail.

Referring to FIG. 5 illustrating a representative portion of a cell core circuit of an SRAM according to an embodiment of the present invention, a precharging and equalizing unit 22 and an equalizing driver 42 have a configuration different from that of the conventional SRAM of FIG. 1.

In FIG. 5, each of the plurality of SRAM cells 1 constituting a memory cell array 10 may include six CMOS transistors P1, P2, and N1, N2, N3, and N4, as in FIG. 1. Each memory cell may be formed as a three-dimensional memory cell called a single stack memory cell or a double stack memory cell in which the six cell transistors are divided and formed on different conductive layers or different semiconductor layers. In FIG. 5, the cell core circuit includes a conventional column path unit 30, a conventional write driver 50, and a conventional sense amplifier 60, but also a novel precharging and equalizing unit 22, in order to store write data in a selected memory cell of the memory cell array 10 and read the data from the selected memory cell, in a manner similar to the operation of the conventional device of FIG. 1. The novel precharging and equalizing unit 22 comprises a first independently controlled precharging and equalizing circuit 2 that operates independently from second precharging and equalizing circuit 3.

In FIG. 5, the plurality of memory cells 1 are connected to the bit line pairs BLi and BLBi laid out in a bit line (vertical) direction, and one of precharging and equalizing circuits 2 and 3 are alternately disposed adjacent to last memory cells (e.g., row n) in each column. Importantly, the precharging and equalizing circuit 2 operates independently from the precharging and equalizing circuit 3. More specifically, the precharging and equalizing circuit 2 is enabled or disabled by an equalizing signal YEQ_0 provided from the equalizing driver 42, and the precharging and equalizing circuit 3 is independently enabled or disabled by the equalizing signal YEQ_1 provided from the equalizing driver 42. Thus, in the data access mode of operation, a plurality of precharging and equalizing circuits (e.g., 2) corresponding to a selected column in an selected memory block may be controlled (enabled or disabled) with a different timing than a plurality of precharging and equalizing circuits (e.g., 3) corresponding to unselected columns.

A column path gate 4 connected to the bit line pair BLi and BLBi and including four transistors P8, P9, N5, and N6 performs switching operation to switchably couple (connect) the bit line pair BLi and BLBi to the section data lines RSDL, RSDLB, WSDL and WSDLB.

The PMOS transistors in the column path gate 4 transfer cell data developed on the bit line pair BLi and BLBi to a read section data line pair RSDL and RSDLB in response to a complementary column select signal Yb. The NMOS transistors in the column path gate 4 function to transfer write data from the write section data line pair WSDL and WSDLB to the bit line pair BLi and BLBi in response to a column select signal Y. In FIG. 5, suffix “_S” is an initial representing “select” and “_DS” are initials representing “deselected” (i.e., unselected). For example, Y_S indicates a column select signal applied to a selected column, and Y_DS indicates a column select signal applied to an unselected column. Of course, the write data is provided by the write driver 50 having an output connected to the write section data line pair WSDL and WSDLB.

In FIG. 5, when a memory cell 1 connected to the bit line pair BL0 and BLB0 is selected, the equalizing driver 42 functions as a bit line coupling reduction unit. The equalizing driver 42 applies an equalization release signal YEQ_0 to the precharging and equalizing circuit 2 connected to the selected bit line pair BL0 and BLB0 when a data access mode of operation such as a write mode of operation is initiated and then applies equalization release signals YEQ_1 to the precharging and equalizing circuit 3 connected to a plurality of corresponding unselected bit line pair BL1 and BLB1 after a predetermined time period in order to reduce capacitive voltage coupling between neighboring bit lines.

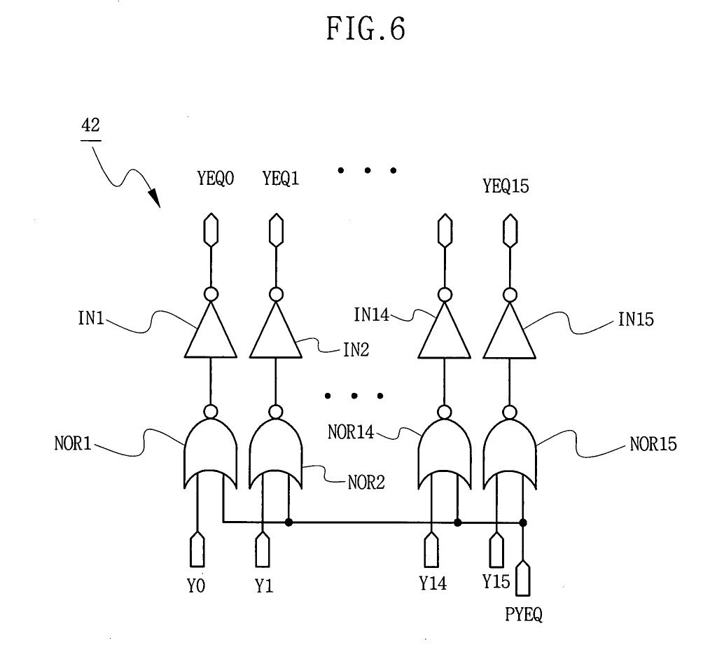

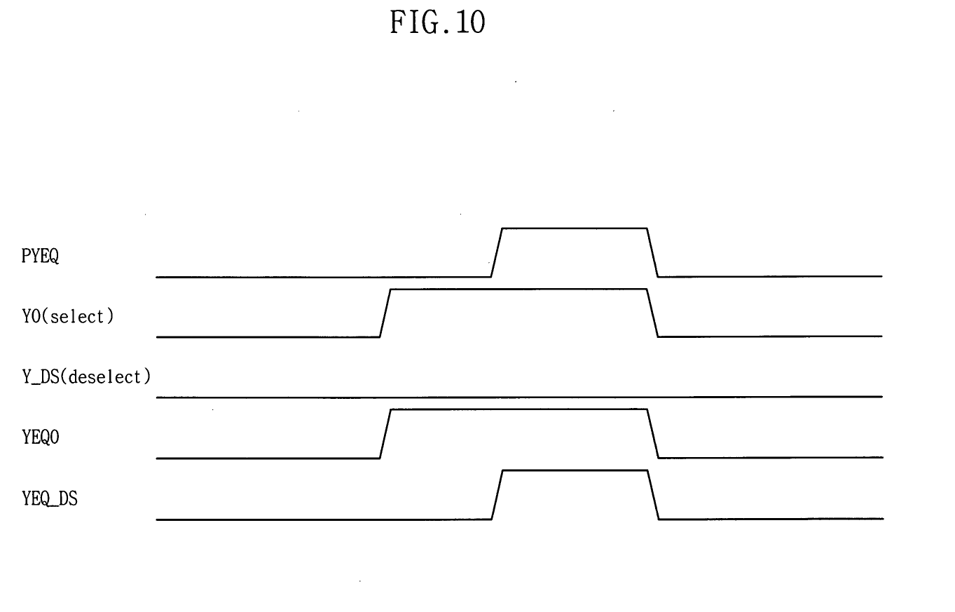

An example of a circuit implementing the functions of the equalizing driver 42 is shown in FIG. 6. FIG. 6 is a circuit diagram illustrating an exemplary equalizing driver 42 shown in FIG. 5. The equalizing driver 42 includes NOR gates NOR1 to OR15 and inverters IN1-IN15 respectively connected to outputs of the NOR gates NOR1 to NOR15 for performing an inverting function. Operation timing of signals input and output by the equalizing driver 42 in FIG. 6 is illustrated in a waveform (timing) diagram of FIG. 10.

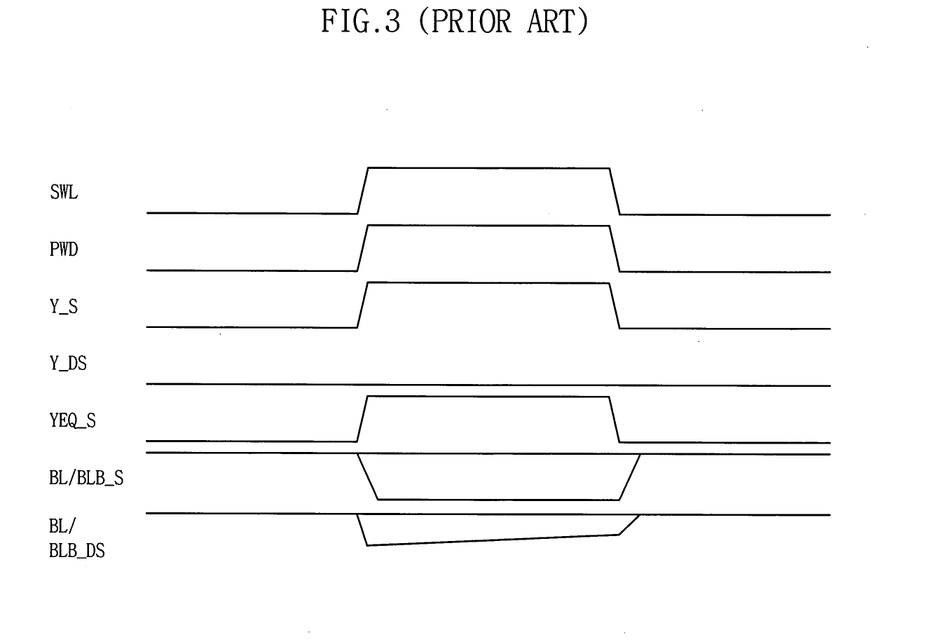

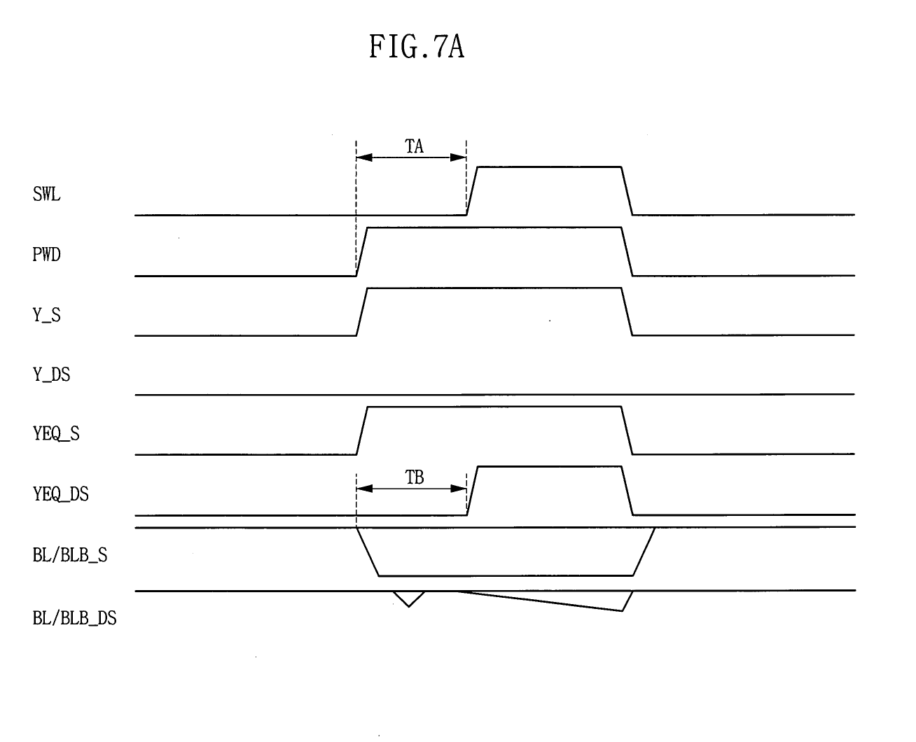

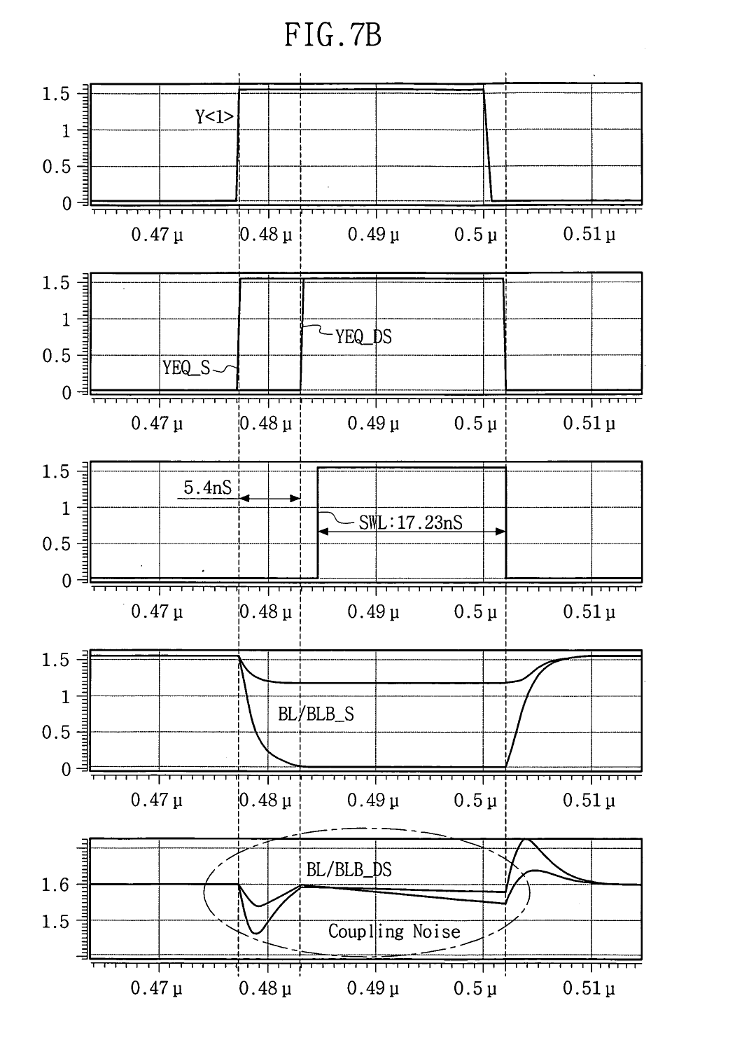

FIG. 10 is a timing diagram illustrating operation timing for various signals in the equalizing driver shown in FIG. 6. Referring to FIG. 10, a precharging and equalizing control signal PYEQ output from the equalizing generator (not shown) in a semiconductor memory device has the waveform labeled PYEQ in FIG. 10. It is to be noted that when the bit line pair BL0 and BLB0 of FIG. 5 is selected, an equalizing signal YEQ_0 applied to the precharging and equalizing circuit 2 has a waveform YEQ0 of FIG. 10. The waveform YEQ0 is output from the inverter IN1 of FIG. 6. Meanwhile, an equalizing signal YEQ_1 applied to the unselected precharging and equalizing circuit 3 has a waveform YEQ_DS of FIG. 10. The waveform YEQ_DS is output from the inverter IN2 and from the other inverters IN3 to IN15 of FIG. 6 when there are fifteen unselected precharging and equalizing circuits 3. In FIG. 10, a waveform Y0 is a column select signal applied to a selected column, and a waveform Y_DS is a column select signal applied to an unselected column. According to the operation timing shown FIG. 10, when the data access mode of operation is initiated, the precharging and equalizing circuit 2 connected to the selected column is first disabled, and then the precharging and equalizing circuit 3 connected to a plurality of unselected columns (fifteen columns when one block includes sixteen columns) is disabled after a predetermined time lapses. Therefore, the equalizing signal YEQ_0 at a high level denotes an equalization release signal or a precharge blocking control signal in the data access mode of operation. In this manner, when the precharging and equalizing circuit 3 connected to the unselected columns is disabled after a predetermined time elapses, it continues to perform the precharging and equalizing operation until the precharging and equalizing circuit 2 connected to the selected column stops its precharging and equalizing operation and then is disabled. Accordingly, strong bit line voltage coupling does not occur (unlike in the conventional case of the waveform BL/BLB_DS of FIG. 3). This difference can be easily understood from a comparison between the waveform BL/BLB_DS of FIG. 7A and the waveform BL/BLB_DS of FIG. 3.

FIG. 7A is a timing diagram illustrating operation timing for various signals in the SRAM of FIG. 5. FIG. 7B is a timing diagram illustrating simulation waveforms of various signals in the SRAM of FIG. 5.

It can be seen from FIG. 7A that the disable time point of the waveform YEQ_DS applied to the unselected precharging and equalizing circuit 3 is delayed for a time period TB from the disable time point of the waveform YEQ_S applied to the selected precharging and equalizing circuit 2. The delay for producing the time period TB is supported by the independent control of the precharging and equalizing circuits 2 & 3 divided into a selected group and an unselected group by the equalizing driver 42. In this case, voltage coupling between bit lines connected to neighboring cells is minimized by delaying a word line enable time point for a time period TA from the enable time point of a write driving enable signal PWD.

A write operation for storing data in a memory cell 1 in the SRAM of FIG. 5 will now be described. In the write operation, when an address is applied to select the memory cell 1, a write driving enable signal PWD is raised to a high level to operate the write driver 50 when a column select signal Y_S applied to the selected column is enabled (a waveform Y_S of FIG. 7A). In a state where the word line enable signal SWL is not yet activated, an equalization release signal YEQ_0 at a high level is applied to disable the precharging and equalizing circuit 2. Accordingly, the precharging and equalizing operation of the bit line pair BL0 and BLB0 is not performed. In this case, the precharging and equalizing operation of neighboring bit line pair BL1 and BLB1 is performed, and the selected bit line pair BL0 and BLB0 has a potential developed as indicated in the waveform BL/BLB_S of FIG. 7A. Accordingly, even though a parasitic capacitance CBLb exists between the bit line BLB0 and the bit line BL1, a potential is not developed between the bit lines BL1 and BLB1 during the precharging and equalizing operation.

After the write driving enable signal PWD is raised to a high level and delayed for a time period TA, the word line enable signal SWL is activated (raised) to a high state. Thus, when write data is stored in the memory cell 1, a high level signal is applied to the first word line SWL_0 in FIG. 5. Further, after the waveform YEQ_S (e.g., YEQ_0) is disabled and delayed for a time period TB, the precharging and equalizing circuit 3 connected to the neighboring bit line pair BL1 and BLB1 stops operation (YEQ_DS, e.g., YEQ_1). Therefore, a developed potential weakly appears between the bit line BL1 and bit line bar BLB1 as indicated in the waveform BL/BLB_DS of FIG. 7A. A coupling noise as indicated in the waveform BL/BLB_DS of FIG. 7A is much smaller than that indicated in the waveform BL/BLB_DS of FIG. 3, which is an improved performance achieved by an aspect of the present invention. As a result, in the write operation of the present invention, since the voltage coupling noise in the waveform BL/BLB_DS of FIG. 7A in the SRAM of FIG. 5 is smaller than that in the waveform BL/BLB_DS of FIG. 3 in the SRAM of FIG. 1, a logic state of the data stored in the neighboring memory cell in the SRAM of FIG. 5 is not easily changed, and the cell data flip phenomenon is minimized or eliminated in the SRAM of FIG. 5. In FIG. 7A, the word line enable signal SWL is activated (raised) into a high state after the write driving enable signal PWD is shifted to a high level and is delayed for the time period TA, as described above. This is optional and is for optimizing a reduction of voltage coupling noise in an SRAM (FIG. 5) according to an embodiment of the present invention.

The key to reducing voltage coupling noise is to independently disable the selected precharging and equalizing circuit (e.g., 2) and the unselected precharging and equalizing circuit (e.g., 3). In this manner, the voltage coupling due to the parasitic capacitor is weakened and the voltage level on the selected bit line bar BLB0 is not substantially affected by the voltage level on the adjacent unselected bit line BL1. Accordingly, data previously stored in a neighboring memory cell connected to the enabled word line SWL_0 is not flipped from 0 to 1 or from 1 to 0.

In FIG. 5, the schematic structure of the SRAM memory cell core based on the two complementary bit line pairs is shown as an example of an SRAM according to an embodiment of the present invention. However, it is to be noted that a plurality of memory cells belonging to the same bit line pair together with a plurality of memory cells belonging to the other bit line pair may constitute one memory cell block in a unit of 16 or 32 columns. A memory cell array 10 (FIG. 5) may comprise plurality of memory cell blocks.

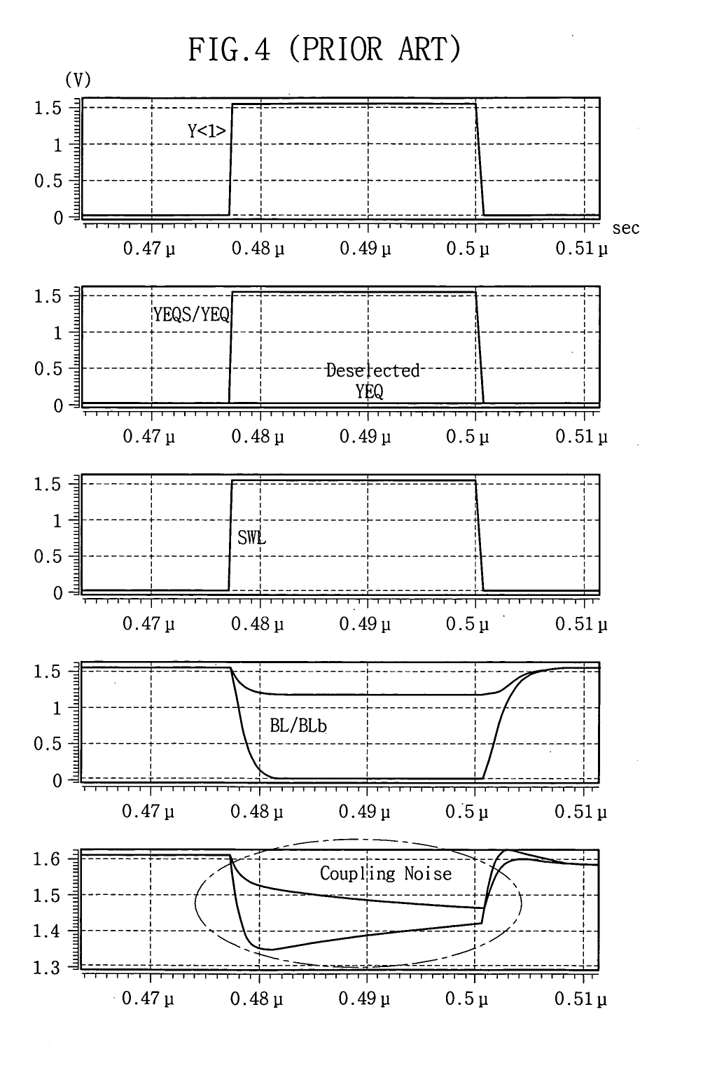

Referring to FIG. 7B, in the several graphs, each horizontal axis indicates time in microseconds and each vertical axis indicates voltage V. A simulation waveform will be easily understood by those skilled in the art since reference numerals on the simulation waveform are the same as or similar to those shown in FIGS. 5 and 7A. For example, Y<1> indicates the column select signal Y, YEQ_S indicates the equalizing signal YEQ_0, and SWL indicates the word line (or section word line). It can be confirmed by a comparison between the graph shown in a bottom of FIG. 7B and the graph shown in a bottom of FIG. 4, that coupling noise is significantly reduced in the SRAM of FIG. 5.

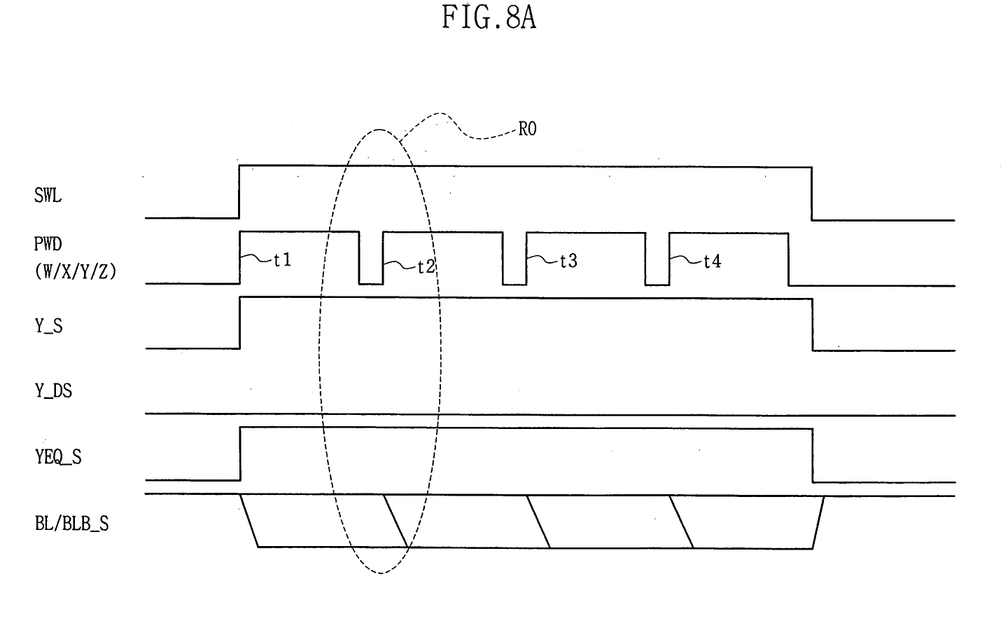

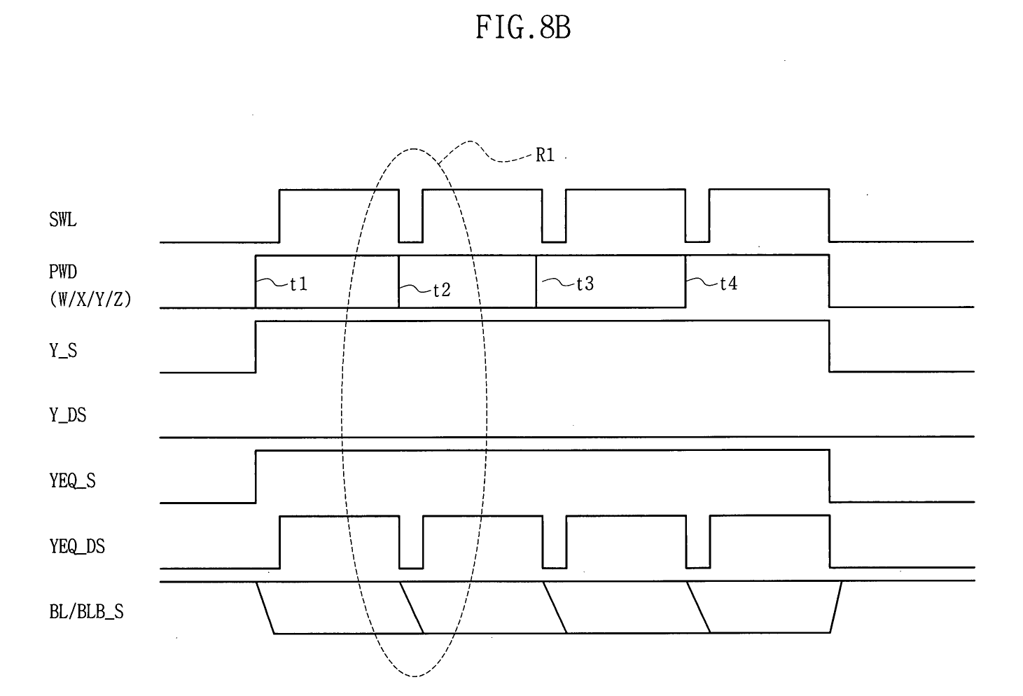

FIGS. 8A and 8B are timing diagrams illustrating a comparison in write operation timing between a conventional technique and an embodiment of the present invention respectively, in a synchronous mode. In FIG. 8B, the disable time point of an equalizing signal YEQ_DS for blocking the operation of the precharging and equalizing circuit (e.g., 2) connected to the unselected bit line pair and the enable time point of the word line SWL are delayed as compared to the corresponding signals of FIG. 8A, thereby minimizing or reducing bit line voltage coupling. Thus, the timing relationship indicated at reference numeral R1 in the write mode of operation significantly reduces coupling noise (as compared to the timing relationship indicated at reference numeral R0).

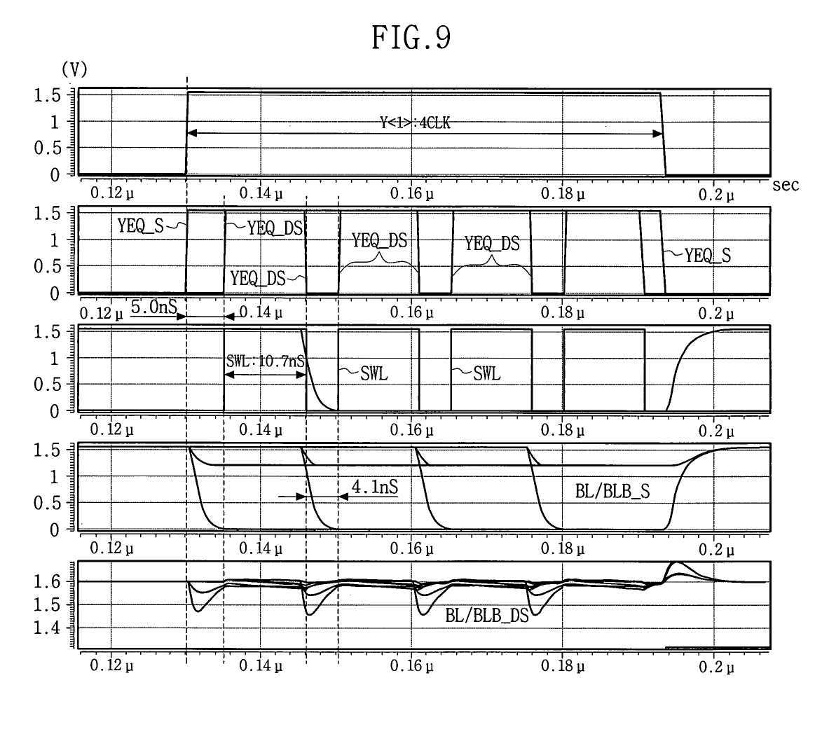

FIG. 9 is a timing diagram illustrating simulation waveforms of write operations in the SRAM of FIG. 5. Signal waveforms appearing over four clock cycles is shown. In the several graphs in FIG. 9, each horizontal axis indicates time in microseconds and each vertical axis indicates voltage V. The simulation waveform will be easily understood by those skilled in the art since reference numerals on the simulation waveform are the same as or similar to those shown in FIGS. 5 and 7A. For example, Y<1> indicates the column select signal Y, YEQ_S indicates the equalizing signal YEQ_0, and SWL indicates a word line (or a section word line). It can be confirmed by a comparison between the graph shown in a bottom of FIG. 9 and the graph shown in the bottom of FIG. 4, that coupling noise is significantly reduced in the SRAM of FIG. 5.

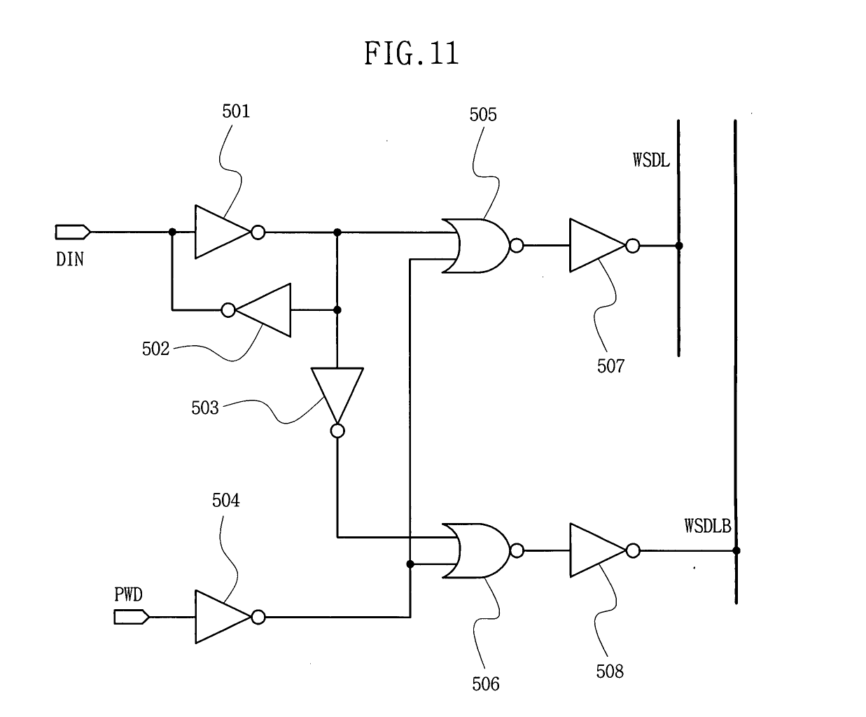

FIG. 11 is a circuit diagram an exemplary circuit for implementing the write driver 50 in FIG. 5. The write driver 50 includes a plurality of inverters 501, 502, 503, 504, 507, and 508, and NOR-gates 505 and 506. When a data DIN dependent output of the inverter 507 is at a high level, an output of the inverter 508 that is complementary to the inverter 507 is at low level, and vice versa.

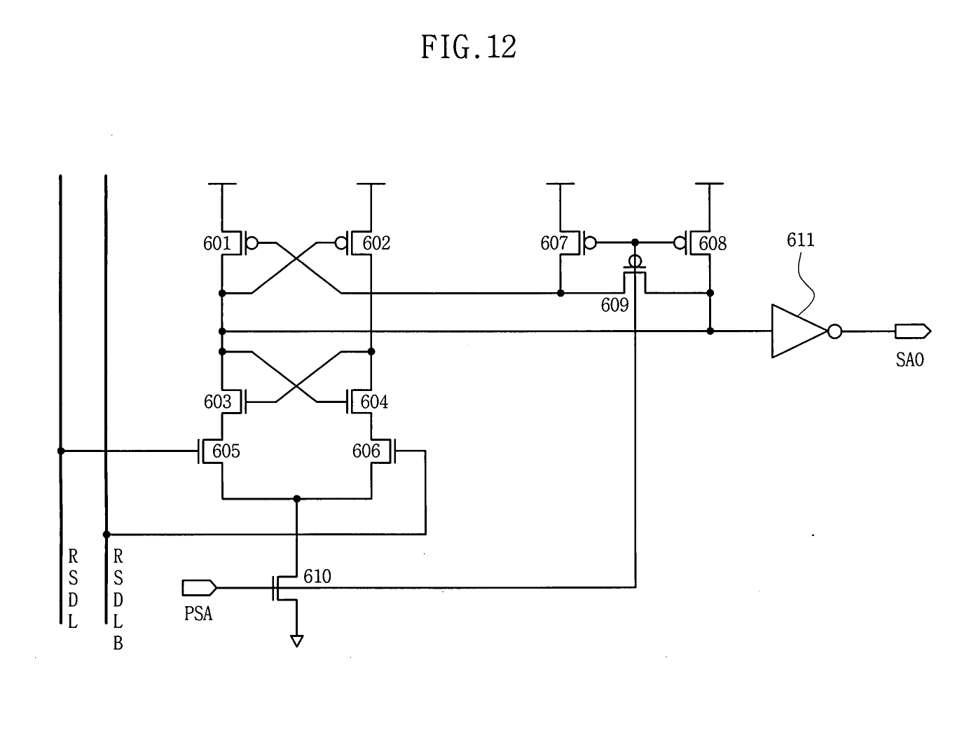

FIG. 12 is a circuit diagram of an exemplary circuit for implementing the sense amplifier 60 in FIG. 5. The sense amplifier 60 includes MOS transistors 601, 602, 603, 604, 605, 606, 607, 608, 609, and 610 and an inverter 611. The sense amplifier, which is enabled when the sensing enable signal PSA is at a high state, is of a well-known differential amplifier type and amplifies a voltage applied at the gates of the two N type MOS transistors 605 and 606 to sense data stored in the selected memory cell.

The foregoing description has sufficiently illustrated that bit line voltage coupling is reduced during the write operations of the SRAM of FIG. 5 according to embodiments of the present invention, and thus the cell data flip phenomenon is prevented.

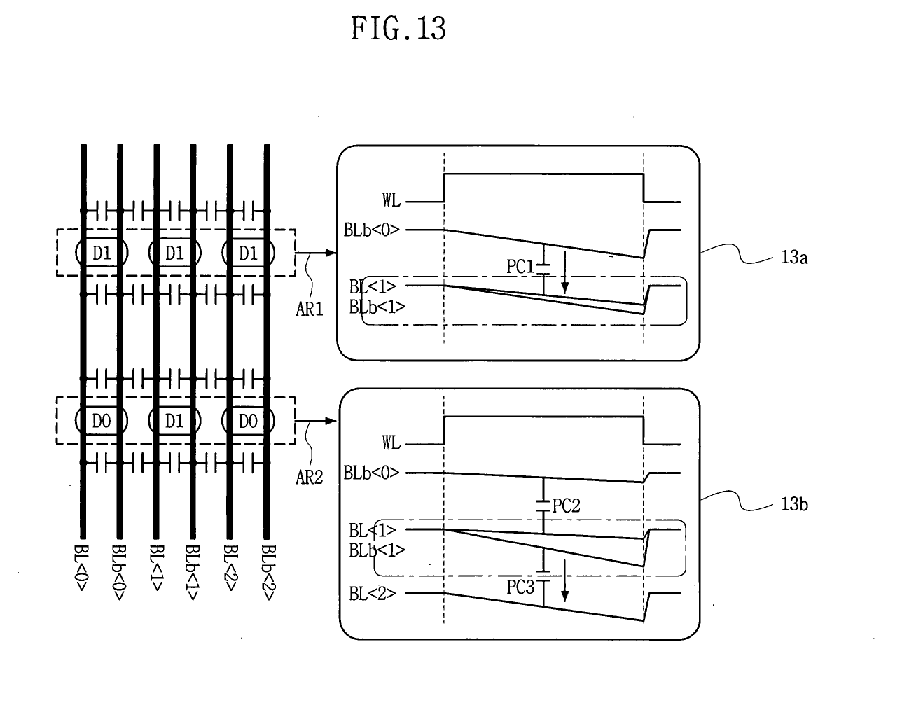

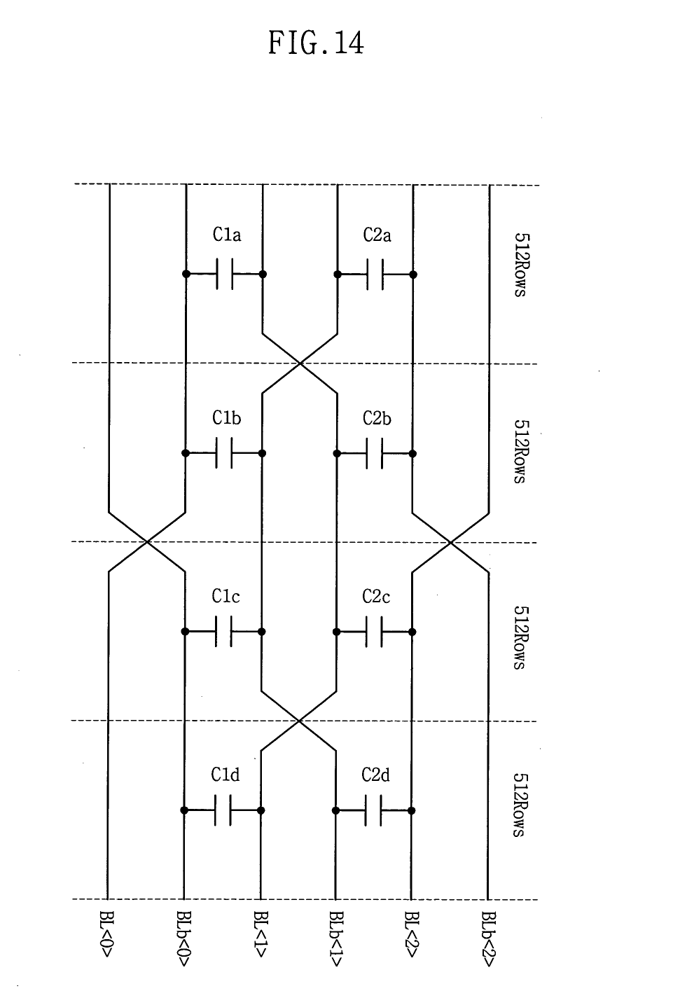

A bit line layout structure for solving a read error problem encountered in the read operation illustrated in FIG. 13 will be described with reference to FIG. 14.

FIG. 14 is a wiring diagram illustrating a bit line layout structure solving a capacitive coupling problem in FIG. 13 according to a variation of the present invention. The bit line layout structure is a twisted-pair bit line structure. Specifically, each bit line pair is laid out in a twisted-pair structure to thoroughly prevent the read error problem that may otherwise be encountered in the read operation. Here, a bit line pair BL<0> and BLb<0> is twisted once per 1024 word lines, a neighboring bit line pair BL<1> and BLb<1> is twisted per 1024 word lines beginning 512 word lines away from the point at which the bit line pair BL<0> and BLb<0> is first twisted. According to the bit line twisted-pair layout structure, bit lines associated with the parasitic capacitor C1a and the parasitic capacitor C1b shown in FIG. 14 are different. The parasitic capacitor C1a is generated by the bit line BL<0> and the bit line BL<1>, and the parasitic capacitor C1b is generated by the bit line BL<0> and the bit line BLb<1>. This arrangement weakens the bit line voltage coupling.

As described above, according to various embodiments of the present invention, the bit line voltage coupling due to the presence of parasitic capacitance between bit lines in different pairs is minimized or reduced in the write and in a read operation. Accordingly, the cell data flip phenomenon is prevented in the write operation, and the read fail is prevented in the read operation. Particularly, in a three-dimensional high-integration static random access memory comprised of a plurality of six-transistor memory cells, device performance can be significantly enhanced.

Meanwhile, the invention has been described using preferred exemplary embodiments. However, it is to be understood that the scope of the invention is not limited to the disclosed embodiments. Rather, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements. For example, the selected precharging and equalizing circuit may be laid out on the first word line, and the unselected precharging and equalizing circuits may be independently disabled. Further, a higher voltage may be temporarily applied when the operation period begins while the precharge level is kept at the first voltage in order to reduce leakage current and enhance a wake-up time.

As described above, according to the present invention, the bit line voltage coupling due to the presence of the parasitic capacitance between bit lines in different bit line pairs is minimized or reduced in the write and read operation. Accordingly, the cell data flip phenomenon is prevented in the write operation, and the read fail is prevented in the read operation.

What is claimed is:

1. A semiconductor memory device, comprising:
a memory cell array having a matrix of memory cells connected, each memory cell being connected to a word line and between a pair of bit lines; and
a first precharging and equalizing circuit connected to a first bit line pair connected to a first memory cell connected to the first word line; and
a second precharging and equalizing circuit connected to a second bit line pair connected to a second memory cell connected to the first word line, wherein the first memory cell is adjacent to the second memory cell.

2. The device according to claim 1, further comprising, a third precharging and equalizing circuit connected to a third bit line pair connected to a third memory cell connected to the first word line, wherein the third memory cell is adjacent to the second memory cell.

3. The device according to claim 2, further comprising, a bit line coupling reduction unit for first applying an equalization release signal to the first precharging and equalizing circuit when a data access mode of operation is initiated, and then applying equalization release signals to the second and third precharging and equalizing circuits connected after a predetermined time lapses.

4. The device according to claim 3, wherein the bit line coupling reduction unit is an equalizing driver.

5. The device according to claim 4, wherein the equalizing driver operates sixteen precharging and equalizing circuits.

6. The device according to claim 1, wherein a word line connected to the first memory cell is enabled a predetermined time after the first precharging and equalizing circuit is disabled.

7. The device according to claim 1, wherein a word line connected to the first memory cell is enabled when the second precharging and equalizing circuit is disabled.

8. The device according to claim 1, wherein the semiconductor memory device is a static random access memory including a the first and second memory cells, each of the first and second memory cells includes six transistors.

9. The device according to claim 8, wherein the six transistors comprise three-dimensional stack memory cells formed on different layers.

10. The device according to claim 1, wherein the first bit line pair is a twisted pair of conductors twisted per each predetermined number of word lines.

11. The device according to claim 10, wherein the first and second bit line pairs are twisted every 1024 word lines.

12. A semiconductor memory device, comprising:
an array of memory cells, each memory cell being connected to a word line pair and between a pair of bit lines; and
a first precharging and equalizing circuit connected to a first bit line pair connected to a first memory cell connected to a first word line; and
a second precharging and equalizing circuit connected to a second bit line pair connected to a second memory cell connected to the first word line, wherein the first memory cell is adjacent to the second memory cell.

13. The device according to claim 12, further comprising, a third precharging and equalizing circuit connected to a third bit line pair connected to a third memory cell connected to the first word line, wherein the third memory cell is adjacent to the second memory cell.

14. The device according to claim 13, further comprising an equalizing driver for applying an equalization release signal to the first precharging and equalizing circuit, and then applying equalization release signals to the second and third precharging and equalizing circuits when the first word line is activated after a write driver is enabled.

15. The device according to claim 14, wherein the equalizing driver operates sixteen precharging and equalizing circuits.

16. The device according to claim 12, wherein the bit line pairs are twisted per each predetermined number of word lines.

17. The device according to claim 16, wherein the bit line pairs are twisted per 1024 word lines.

18. The device according to claim 12, wherein the semiconductor memory device includes a write driver and a sense amplifier.

19. The device according to claim 12, wherein the semiconductor memory device is a static random access memory including a the first and second memory cells, each memory cell includes six transistors.

20. The device according to claim 19, wherein the six transistors comprise three-dimensional single stack memory cells formed on different layers.

21. A static random access semiconductor memory device, comprising:
an array of memory cells, each memory cell being connected to a word line and between a pair of bit lines; and
a word line enable delay unit for delaying a driving time point of a selected word line in a data access mode of operation from a time point at which a bit line pair of a selected memory cell is equalized.

22. The device according to claim 21, wherein the data access mode of operation is a write mode of operation.

23. The device according to claim 21, wherein the bit line pairs are twisted per each predetermined number of word lines.

24. A method for performing a write operation in a semiconductor memory device comprising a first memory cell connected to a first word line and between a first pair of bit lines and a second memory cell connected to the first word line and between a second pair of bit lines, the method comprising:
applying an equalization release signal to a first precharging and equalizing circuit connected to the first bit line pair;
applying an equalization release signal to a second precharging and equalizing circuit connected to the second bit line pair when the first word line is activated after a write driver is enabled; and
writing write data to the first memory cell before the second precharging and equalizing circuit connected to the second bit line pair is disabled.

25. A method for performing write operation in a semiconductor memory device comprising an array of memory cells, each memory cell having three-dimensional stack and being connected to a word line and between a pair of bit lines, the method comprising:
applying an equalization release signal to a first precharging and equalizing circuit connected to a first pair of bit lines;
applying equalization release signals to a second precharging and equalizing circuit connected to a second pair of bit lines and to a third precharging and equalizing circuit connected to a third pair of bit lines when a word line is activated after a write driver is enabled; and
writing write data to a first memory cell connected to the word line and between the first pair of bit lines immediately after the second and third precharging and equalizing circuits are disabled.
